(19) United States
(12) Patent Application Publication
(10) Pub. No.: US 2009/0130854 A1
(43) Pub. Date: May 21, 2009

(54) PATTERNING STRUCTURE AND METHOD FOR SEMICONDUCTOR DEVICES

(75) Inventor: Chi-Pin LU, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: MACRONIX INTERNATIONAL CO., LTD., Hsinchu City (TW)

(21) Appl. No.: 11/943,900

(22) Filed: Nov. 21, 2007

(51) Int. Cl. H01L 21/311

(52) U.S. Cl. 438/703; 257/E21.249

(57) ABSTRACT

Methods for forming a pattern layer over a target layer are disclosed. The methods use a novel low temperature spacer structure which results in a pattern layer having a decreased pattern pitch versus conventional patterning using photolithography. The decreased pattern pitch allows the target layer to be divided into multiple regions separated by a small distance, which in turn allows for greater density and device miniaturization. The structure and methods may be applied to patterning a word line layer in a memory device.

### COPYRIGHT NOTICE

A portion of the disclosure of this patent document contains material which may be subject to copyright protection. The copyright owner has no objection to the facsimile reproduction by anyone of the patent document or the patent disclosure as it appears in the Patent and Trademark Office patent file or records, but otherwise reserves all copyright rights.

### TECHNICAL FIELD

The invention relates generally to methods of manufacturing memory devices and, more particularly, to a patterning structure and method for decreasing a pattern pitch using the same.

### BACKGROUND

Memory devices have seen explosive growth with the advancement of electronic applications, such as memory cards, portable electronic devices, cell phones, MP3 players, digital still and video cameras, and other consumer electronics. Application requirements for low cost, power consumption, and high performance are driving memory design to different architectures. Device miniaturization is another goal; and such miniaturization may be achieved, for example, by increasing the density of word lines by decreasing the spacing between word lines. This spacing is controlled, for example, by patterning a word line layer using a photolithographic process (using, for example, a 193-nm ArF excimer laser). The pattern layer is used to mask the word line layer so that an etching process may divide the word line layer into multiple regions, which may correspond to multiple rows in a memory device. However, factors such as the resolution of available photolithography tools put a lower limit on such spacing. It is desirable to decrease the pattern pitch, defined as the word line length plus the spacing distance, without requiring new tools or complex processes.

### SUMMARY

According to another aspect of the invention, a method for forming a pattern layer over a target layer is disclosed. The method includes forming a first pattern layer over a target layer, the first pattern layer comprising a first column and a second column, the first and second columns having a first width and being separated by a first distance. Spacers are formed between the first and second columns wherein a trench is provided between two opposing spacers. A filler layer is formed in the trench, the filler layer comprising a third column having the same width as the first and second columns. The spacers are then removed. The resulting structure includes the first column and the second column, and each is separated from the third column by a second distance less than the first distance. The first, second, and third columns comprise a second pattern layer over the target layer whose pattern pitch is less than that of the first pattern layer.

### BRIEF DESCRIPTION OF DRAWINGS

The foregoing summary, as well as the following detailed description, will be better understood when read in conjunction with the appended, exemplary drawings. It should be understood, however, that the invention is not limited to the precise arrangements and instrumentalities shown.

FIGS. 1-8 illustrate processing steps according to one example of a method for forming a pattern layer over a target layer;

FIG. 9 is a flow diagram illustrating one example of a method for forming a pattern layer over a target layer.

### DETAILED DESCRIPTION

Reference will now be made in detail to the exemplary embodiments of the invention, examples of which are illustrated in the accompanying drawings. Wherever possible, the same reference numbers will be used throughout the drawings to refer to the same. The following examples disclose a novel low temperature spacer layer structure and process for forming the same and a method for forming a pattern layer over a target layer, described in further detail below.

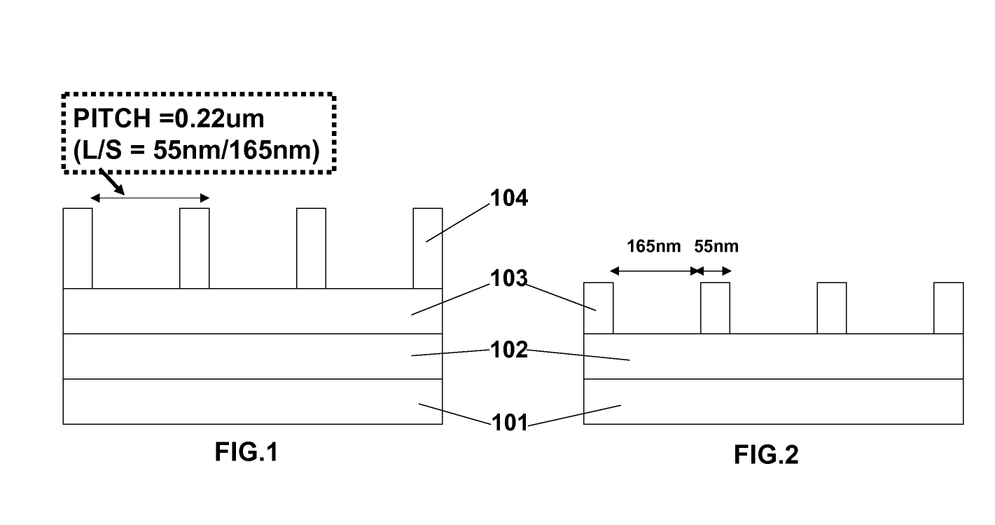

FIGS. 1-8 illustrate processing steps of a method of forming a pattern layer over a target layer according to one example of the invention. In FIG. 1, there is a target layer 101. The target layer 101 may be, for example, a WSix or polysilicon word line layer in a memory device. A first hard mask 102, such as an LPTEOS oxide layer, has been formed over the target layer 101. A second hard mask 103, such as a poly film layer, has been formed over the first hard mask. A photoresist layer 104 has been applied over the second hard mask 103 for patterning with a 193 nm ArF lithograph. In this example, the mask width (which corresponds to the desired feature length, or L) is 55 nm, and the opening distance (or spacing S) is 165 nm. The original pattern pitch (L+S) in this example is 0.22 um (220 nm). In FIG. 2, the pattern has been copied directly onto the first hard mask 102, following an etch of the second hard mask layer 103. The remaining portion of the second hard mask layer 103 forms a first pattern layer. The first pattern layer comprises a first set of columns, each column being 55 nm wide and separated from an adjacent column by a distance of 165 nm.

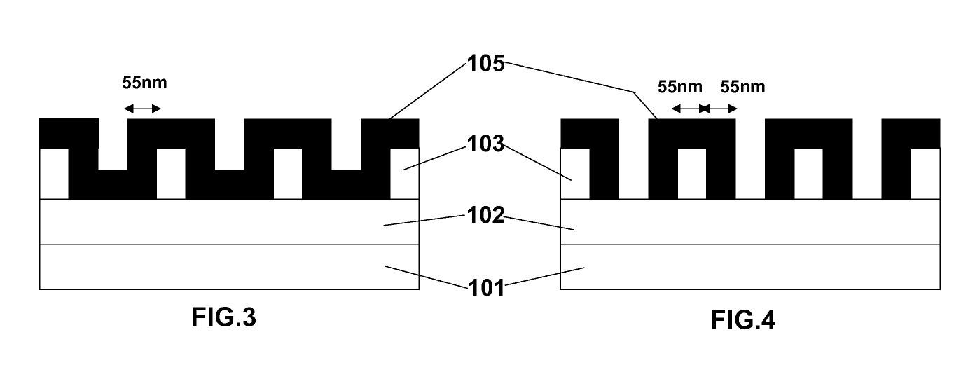

In FIG. 3, a conformal layer 105 has been formed over the first pattern layer and between the first set of columns. The conformal layer 105 may be, for example, SiO₂ and may be formed by an atomic layer deposition (ALD) process. For example, the SiO₂ layer may be formed at 200 C at a deposition rate of 225 A/min. The sidewall step coverage is around 95%. The conformal layer 105 in this example has a thickness of 55 nm. In FIG. 4, a plurality of trenches has been formed in the conformal layer 105, creating a plurality of spacers (referred to as conformal layer 105 or spacers 105). For example, an anisotropic plasma etch process may be used to etch through the bottom of the spacer layer and stop on the first hard mask layer 102.

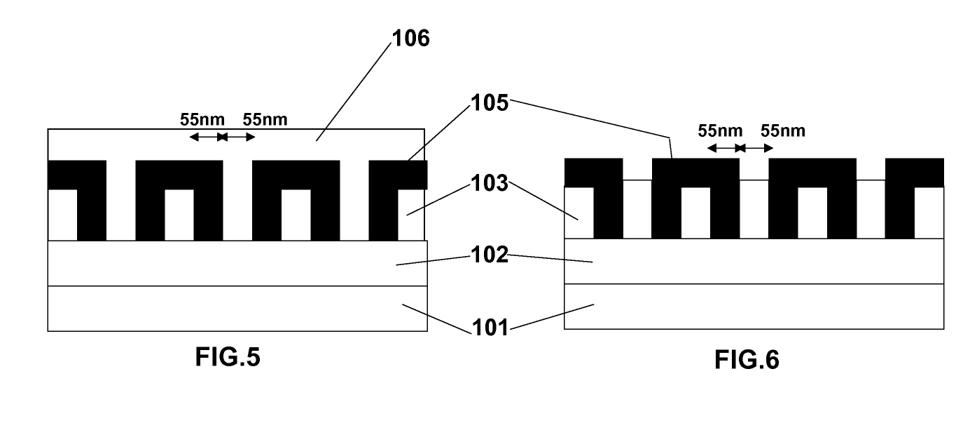

In FIG. 5, a filler layer 106 has been formed over the spacers 105 and in the plurality of trenches. The filler layer 106 may be, for example, a poly film deposited at 520 C using silane gas (SiH₄). In FIG. 6, the filler layer has been etched down to the spacers 105. For example, a chemical mechanical polishing (CMP) process may be used. The remaining portions of the filler layer 106 comprise a second set of columns. Each of the second set of columns has a width of 55 nm, which is the same as the width of each of the first set of columns in the first pattern layer.

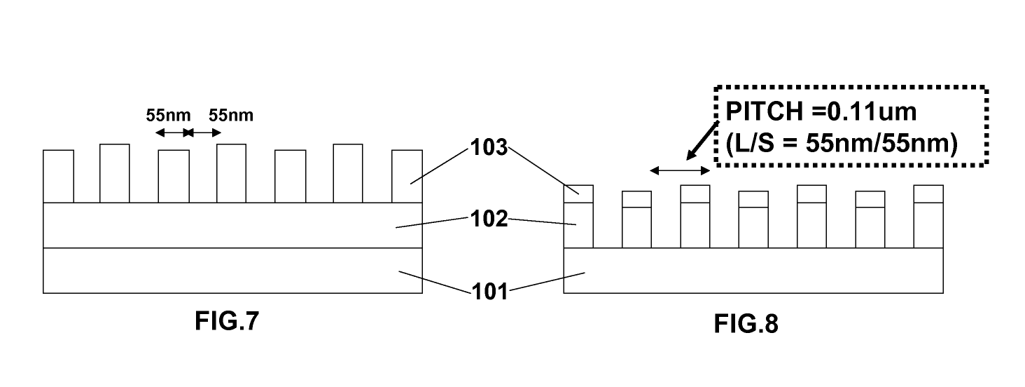

In FIG. 7, the spacers have been removed. For example, a dilute hydrofluoric acid (DHF) cleaning process at 25 C, using a 50:1 H₂O:HF ratio may be used. The resulting structure includes the first set of columns of the first pattern layer and the second set of columns from the filler layer 106. Each of these columns in the first and second sets is 55 nm wide and is separated by a distance of 55 nm from an adjacent column. In this manner, the first set of columns and the second set of columns form a second pattern layer. The pitch of the second pattern in this example is 0.11 um (110 nm). In FIG. 8, this second pattern has been copied directly to the first hard mask layer 102 by an appropriate etch process. The final pattern pitch over the target layer 101 is 0.11 um, and the word line length is 55 nm.

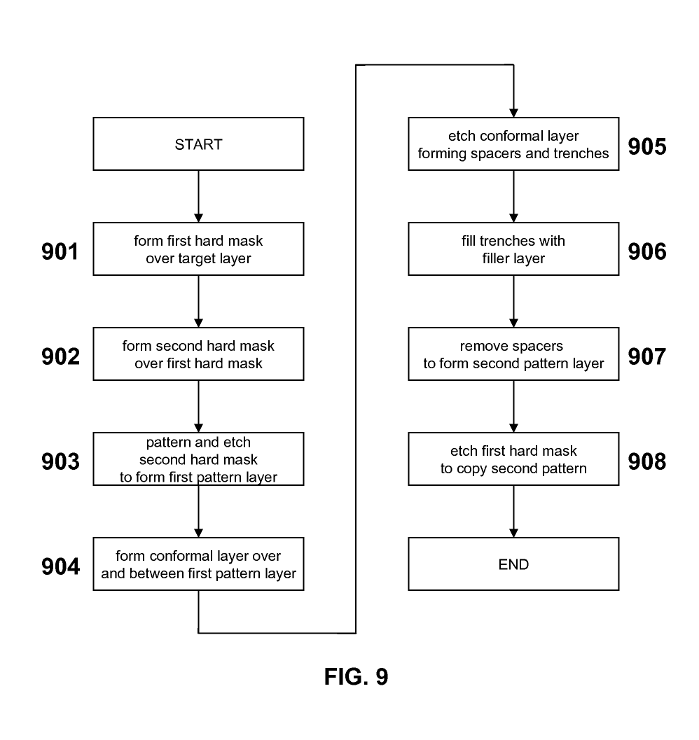

FIG. 9 is a flow diagram illustrating a method for forming a pattern layer over a target layer according to one example of the invention. A first hard mask layer is formed over the target layer, step 901. A second hard mask layer is formed over the first hard mask, step 902. The second hard mask layer is patterned and etched to form a first pattern layer, step 903. The first pattern layer comprises a first set of columns. Each column has the same width and is separated from an adjacent column by a first distance. The first pattern has a pitch equal to the width plus the first distance. A conformal layer is formed over and between the first pattern layer, step 904. The conformal layer may be formed, for example, by a low-temperature atomic layer deposition (ALD) process. The conformal layer is etched to form a plurality of spacers and trenches, step 905. The trenches extend down to the first hard mask layer, and have a width equal to the width of each of the first set of columns in the first pattern layer. The trenches are filled with a filler layer, step 906. The filler layer may be etched back, for example, using a chemical mechanical polishing (CMP) process. The spacers (i.e., remaining conformal layer) are removed, step 907. The remaining structure includes the first set of columns of the first pattern layer and a second set of columns from the filler layer. These columns together form a second pattern layer. Each of the columns has the same width and is separated from an adjacent column by a second distance, which is smaller than the first distance of the first pattern. The pitch of the second pattern, equal to the width of each column in the second pattern layer plus the second distance, is therefore smaller than the pitch of the first pattern.

It will be appreciated by those skilled in the art that changes could be made to the examples described above without departing from the broad inventive concept thereof. It is understood, therefore, that this invention is not limited to the particular examples disclosed, but it is intended to cover modifications within the spirit and scope of the present invention as defined by the appended claims.

I claim:

1. A method for patterning a semiconductor device, the method comprising:
forming a first pattern layer over a target layer, the first pattern layer comprising a first column and a second column, the first and second columns having a first width and being separated by a first distance;
forming spacers on the sidewalls of the first and second columns wherein a trench is provided between two opposing spacers;
forming a filler layer in the trench, the filler layer comprising a third column having the same width as the first and second columns; and
removing the spacers;
wherein the first column and the second column are each separated from the third column by a second distance less than the first distance and the first, second, and third columns comprise a second pattern layer over the target layer.

2. The method according to claim 1, wherein forming the first pattern layer over a target layer comprises forming a pattern layer over a word line layer.

3. The method according to claim 1, wherein forming the first pattern layer comprises forming a pattern by photolithography and transferring the pattern to a hard mask layer by etching.

4. The method according to claim 1, wherein forming the spacers comprises using an atomic layer deposition process.

5. The method according to claim 1, further comprising etching the target layer based on the second pattern layer.

6. A method comprising:
forming a first pattern layer over a target layer, the first pattern layer comprising a first plurality of columns, each of the first plurality of columns having a width and being evenly spaced and separated by a first distance from an adjacent column;
forming a conformal layer over the first plurality of columns;
removing a portion of the conformal layer to form spacers on the sidewalls of the first plurality of columns and a plurality of trenches between opposing spacers;
forming a filler layer in the plurality of trenches, the filler layer comprising a second plurality of columns, each of the second plurality of columns having the same width as each of the first plurality of columns; and
removing the spacers;
wherein each of the first plurality of columns is separated from one of the second plurality of columns by a second distance less than the first distance, and the first plurality of columns and the second plurality of columns comprise a second pattern layer over the target layer.

7. The method according to claim 6, wherein forming the first pattern layer over a target layer comprises forming a pattern layer over a word line layer.

8. The method according to claim 6, wherein forming the first pattern layer comprises forming a pattern by photolithography and transferring the pattern to a hard mask layer by etching.

9. The method according to claim 6, wherein forming the spacers comprises using an atomic layer deposition process.

10. The method according to claim 6, further comprising etching the target layer based on the second pattern layer.
